(19) United States
(12) Patent Application Publication
(10) Pub. No.: US 2016/0165767 A1
(43) Pub. Date: Jun. 9, 2016

(54) Taper Composite Metal-Matrix Composites and Fabricating Methods for the Same

(71) Applicant: Chung Yuan Christian University, Taoyuan City (TW)

(72) Inventors: Tsung-Yen TSAI, Taoyuan City (TW); Cheng-Ming AI, Taoyuan City (TW); Te-Hsuan HUANG, Hualien County (TW)

(21) Appl. No.: 14/868,109

(22) Filed: Sep. 28, 2015

(30) Foreign Application Priority Data
Dec. 5, 2014 (TW) 103142295

(51) Int. Cl. H05K 9/00; B22F 1/00; C08K 3/08; B05D 5/00; C08K 7/00; B22F 9/24; B05D 1/36

(52) U.S. Cl. CPC H05K 9/0083; B22F 9/24; B22F 1/0025; B05D 1/36; B05D 5/00; C08K 7/00; C08K 3/08; C08K 2003/0881; C08K 2003/0856; C08K 2003/0862; C08K 2003/085; C08K 2003/0893; C08K 2003/0812

(57) ABSTRACT

The invention provides a taper composite metal-matrix composite, inclusive of a taper composite metal which forms a plurality of taper metal nanorods on a flake metal substrate and a photocurable polymer such as photocurable epoxy or photocurable PMMA. A taper composite metal-matrix composite is prepared from a blend comprising taper composite metal and a photocurable polymer to produce electromagnetic wave shielding and adsorbing effect, and diminish the target infrared thermal radiation.

### FIELD OF THE INVENTION

The present invention relates to a taper composite metal-matrix composite, particularly, relates to a taper composite metal-matrix composite capable of electromagnetic shielding and absorption, and wherein electromagnetic, wave is in the wavebands of millimeter wave and mid-infrared rays.

### BACKGROUND OF THE INVENTION

Electromagnetic radiation is classified into low frequency to high frequency or high wavelength to low wavelength, which including, radio in the wavelength range of 1 mm to 1 km and the frequency range of 300 GHz to 3 Hz, microwave in the wavelength range of 1 mm to 1 m and the frequency range of 300 GHz to 3 MHz, infrared rays in the wavelength range of 750 nm to 1 mm and the frequency range of 450 THz to 300 GHz, visible light, ultraviolet ray, X ray, and gamma ray. Furthermore, from high frequency to low frequency, radio can be further classified into very high frequency (VHF), high frequency (HF), medium frequency (MF), low frequency (LF), very low frequency (VLF), ultra low frequency (ULF). super low frequency (SLF), extremely low frequency (ELF). Microwave is further classified into extremely high frequency (EHF), super high frequency (SHF) and ultra-high frequency (UHF). Infrared ray is classified into near infrared (NIR), mid infrared (MIR), and far infrared (FIR).

With science and technology in progress, the specifications of telecommunication products are being improved along with the increscent problem of electromagnetic interference (EMI). Take a citizen system as an example, that the digitization and high frequency of a variety of electrical and mechanical equipments brings electromagnetic interference, and other equipments, such as 3C product, are easily subject to the electromagnetic interference. Thus, for preventing from the electromagnetic interference, material capable of electromagnetic, absorption can apply to be attached onto IC chips, transmission lines, cables, printed circuit boards, or cases. Take a military system as an example, such a material often applies to stealth technology. A beam of radio wave from radar reaches to an object and is reflected by the object. The reflected beam of radio wave is detected by a radar receiver, and then the distance, the direction and the height of the object may be measured by this way. Consequently, technologies such as radar proof detection and infrared ray proof detection have been developed.

The wavebands of traditional electromagnetic shielding or absorption are in the range of radio wave, such as radio wave in the range of 450 kHz to 1 GHz may cause damage on computer components, radio wave in the range of 500 kHz to 10 MHz may cause damage on general electrical industry. Microwave often apples to air defense, missile and target measurement in military system. Millimeter waveband in high frequency range of microwave, which is equivalent to detection range of microwave radar. is not frequently used in the citizen system, as well as the military system. The millimeter waveband can enhance resolution in azimuth and measurement on angle accuracy of radar, and is beneficial to counter electrical interference, noise wave interference. Thus, the millimeter waveband has been gradually applied to citizen and military system, such as terrain-following system, missile fuse, marine navigation, and detection system for low-altitude-flying-target, ground target, or outer space target.

Detection of counter infrared thermal radiation is a very important task on the military application. To reduce the probability of infrared thermal radiation from a target object to be detected, the coating or painting of infrared ray absorption material is often used, as well as the improvement on aircraft structure or the cooling of outer layer of aircraft.

However, there is little material to be used in not only electromagnetic shielding and absorption but also shielding and absorption in millimeter waveband, and there is little information about shielding and absorption in millimeter waveband and reducing infrared thermal radiation from a target object to be published. Thus, the present invention provides a material capable of shielding and absorption in millimeter waveband and reducing infrared thermal radiation from the target object, and the material of the present invention can broadly apply to military stealth technology, electrical equipment, aerospace science, and livelihood product.

### SUMMARY OF THE INVENTION

Accordingly, the present invention provides a taper composite metal-matrix composite, inclusive of a taper composite metal which forms a plurality of taper metal nanorods on a flake metal substrate and a photocurable polymer such as photocurable epoxy or photocurable PMMA. A taper composite metal-matrix composite is prepared from a blend comprising taper composite metal and a photocurable polymer to produce electromagnetic wave shielding and adsorbing effect, and diminish the target infrared thermal radiation.

A fabricating method of taper aluminum-iron matrix composite includes the steps: (1) an aluminum solution is formed by pouring deionized water into a beaker having flake aluminum powder and stirring; (2) a solution of ferric chloride is prepared by solving ferric chloride with deionized water; (3) the aluminum solution reacts with hydrochloric acid completely and the solution of ferric chloride adds into the reacted aluminum solution to form a taper bimetallic aluminum-iron, wherein a plurality of taper iron nanorods are formed on surface of the flake aluminum powder; (4) filtering by air suction and water rinsing are implemented; and (5) the taper bimetallic aluminum-iron and a photocurable polymer are blended to form a taper aluminum-iron matrix composite.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a cross-sectional diagram illustrating a taper composite metal according to the present invention.

FIG. 2 is a topogaphy illustrating the atomic force microscopy (AFM) of bimetallic aluminum-iron according to the present invention.

FIG. 3 is a flow chart illustrating the formation method of bimetallic aluminum-iron according to the present invention.

FIG. 4 is a diagram illustrating reflection loss on millimeter wave for PMMA taper aluminum-iron matrix composite according to the present invention.

FIG. 5 is a diagram illustrating reflection loss on millimeter wave for epoxy taper aluminum-iron matrix composite according to the present invention.

FIG. 6 is a flow chart illustrating the formation method of the taper aluminum-iron matrix composite according to the present invention.

### DETAILED DESCRIPTION OF THE PREFERRED EMBODIMENT

The purpose of the taper aluminum-iron matrix composite in the present invention and the fundamental principle of electromagnetic shielding and absorption are well-known by one having general knowledge in the art, so they will not be illustrated in detail in the following paragraphs, except of specific functions and implement of each components m the taper aluminum-iron matrix composite of the present invention. Meanwhile, the following more detailed description of the embodiments of apparatus and methods in accordance with the present disclosure, as represented in the Figures, is not intended to limit the scope of the disclosure. The presently described embodiments will be understood by reference to the drawings, and the drawings are not necessarily to scale. This invention is not limited to the particular embodiments disclosed, but it is intended to cover modifications within the spirit, and scope of the present invention as defined by the appended claims.

The taper aluminum-iron matrix composite in the present invention can be used in various fields, not limited to a military system. According to similar principles, such a taper aluminum-iron matrix composite can be used in the fields that electromagnetic shielding and absorption are necessary to reduce infrared thermal radiation from a target object, such as electrical products, clothes, architecture, and livelihood products. However, the use in the technical fields of aerospace and military industries will be illustrated in the following paragraphs.

The function of electromagnetic shielding called in the present invention may prevent incident electromagnetic wave from the interior of a material by reflecting or refracting the incident electromagnetic wave, and a material of the function generally has high electrical conductivity. Taking a fighter or a bomber as an example, it is necessary for it to have the function of electromagnetic shielding to prevent exterior signal from disturbing telecommunication and control system. The principle of electromagnetic absorption called means to convert incident radar wave into heat loss by resonance, electrical loss or magnetic loss method to reduce reflectivity of electromagnetic wave. Taking the fighter or the bomber as an example, too, with the function of electromagnetic absorption, the fighter or the bomber can prevent itself from being detected in early time by radar of enemies and further enhance its own existence chance and capacity of sudden attacking. Millimeter wave, also called extremely high frequency (EHF), has a range of frequency between 30 GHz and 300 GHz, and a range of wavelength between inure and 10 mm. The range of wavelength for mid infrared ray (MIR) is between 3 um and 50 um. Photo free-radical polymerization means to pass light into a photosensitive component to generate a series of photo-physical or photo-chemical reactions and further generate active free radical groups. Under the initiation of the active free radical groups, monomers can be polymerized to go polymerization reaction, which can convert liquid resin into curable polymer.

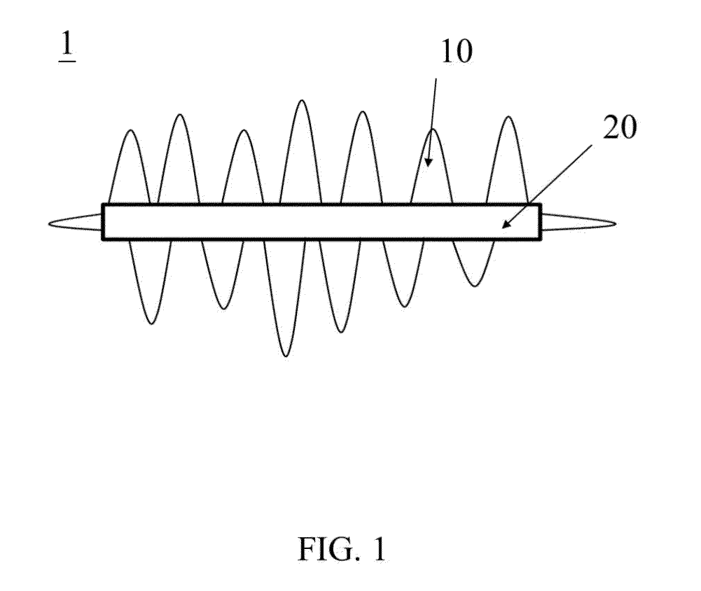

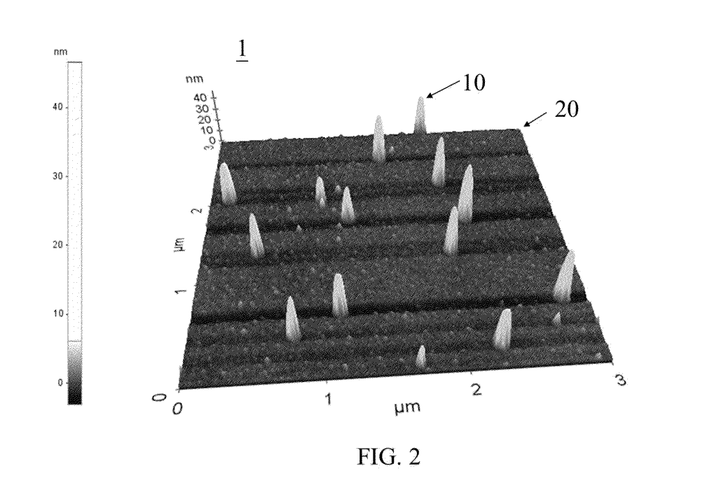

FIG. 1 is a cross-sectional diagram illustrating a taper composite metal according to the present invention. Please refer to FIG. 1, a taper composite metal 1 includes a plurality of taper metal nanorods 10 on a flake metal substrate 20. These taper metal nanorods 10 may be deposited spaced at regular or irregular intervals, and the arrangement of identical space intervals is preferred. FIG. 2 is a topography illustrating the atomic force microscopy (AFM) of bimetallic aluminum-iron according to the present invention. In FIG. 2, the taper metal nanorods 10 grow in the height of about 5 nm to 100 nm and both the length and the width of about 5 nm to 10 nm. It is noted that the length and the width of the taper metal nanorod 10 are the side length and the side width of a boundary between the taper metal nanorod 10 and the flake metal substrate 20. The height of each taper metal nanorod 10 is adjustable dependent on different conditions, and preferably; the height of the taper metal nanorod 10 is about 30 nm to 40 nm. The material of the taper metal nanorods 10 may be titanium, iron, nickel, copper, zinc, or aluminum, and preferably the taper metal nanorods 10 are taper iron nanorods. The material of the flake metal substrate 20 may be titanium, iron, nickel, copper, zinc, or aluminum, the grain sizes of the taper metal nanorods 10 may be about 1 um to 500 um, and preferably the flake metal substrate 20 is aluminum powder in the flake form. It is noted that the material of the taper metal nanorods 10 can be bimetallic or multi-metallic selected from titanium, iron, nickel, copper, zinc, or aluminum, not limited to monometallic. The number and the growth heights of the taper metal nanorods 10 can be controlled under different preparation conditions and measured in a mean roughness Rz (DIN). In one case, the value of the mean roughness is from 30 to 40, and there are one to two taper metal nanorods 10 on the flake metal substrate 20 in the unit area of square micrometers. In the case, the mean roughness Rz (DIN) is acquired by sampling five taper metal nanorods 10 on the flake metal substrate 20 to measure their five heights and average the summation of the five heights, and then a range representing a number of mean values may be got in this way. Such the taper composite metal 1 including the taper metal nanorods 10 and the flake metal substrate 20 is beneficial to electromagnetic shielding and absorbing, as well as reducing thermal as radiation of infrared rays from a target object.

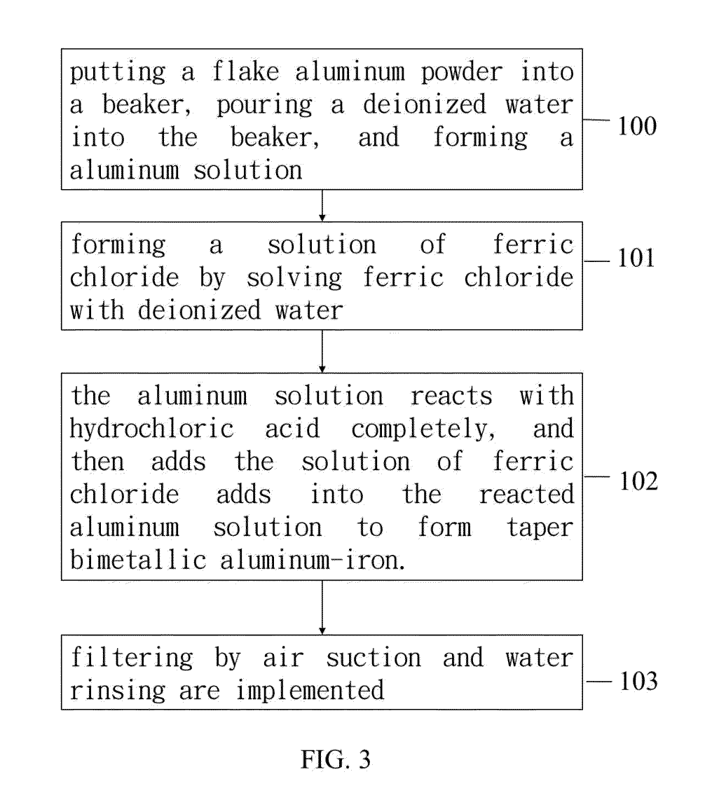

FIG. 3 is a flow chart illustrating the formation method of bimetallic aluminum-iron according to the present invention. Please refer to FIG. 3, step 100: flake aluminum powder in the grain sizes of 1 um to 500 um is put into a beaker, deionized water is poured into the beaker, and aluminum solution is got by stirring and mixing them. Step 101: solution of ferric chloride is formed by solving ferric chloride with deionized water. Step 102: the aluminum solution reacts with hydrochloric acid completely, and then the solution of ferric chloride adds into the reacted aluminum solution to form taper bimetallic, aluminum-iron. After reaction, a plurality of taper iron nanorods is formed on the surface of the flake aluminum powder. The heights of the taper iron nanorods are adjustable by operating different experiment conditions. The heights of the taper iron nanorods are about 5 nm to 100 nm, and the heights of 30 nm to 40 nm are preferable. Step 103: filtering by air suction and water rinsing are implemented.

A taper aluminum-iron matrix composite is provided in the present invention, which includes the taper bimetallic aluminum-iron and polymer material. The taper aluminum-iron matrix composite may be formed by blending the taper bimetallic aluminum-iron of 15 wt % to 20 wt % and the polymer material. Both the taper bimetallic aluminum-iron and the polymer material have the function of electromagnetic shielding and absorbing, as well as reducing thermal radiation of infrared rays from the target object. Especially, they are beneficial to shielding the wavelength range of millimeter wave and mid-infrared rays. In this embodiment, the polymer material includes photocurable polymer, for example, poly(methyl methacrylate (PMMA) or epoxy. Furthermore, the epoxy may include at least one of bisphenol A epoxy resin, bisphenol S epoxy resin, bisphenol F epoxy resin, bisphenol P epoxy resin, hydrogenated bisphenol A epoxy resin, hydroxymethyl bisphenol A epoxy resin, polyether epoxy resin, olyurethane modified epoxy resin, polysiloxane modified epoxy resin, Novolac epoxy resin, aliphatic epoxy resin, and heterocyclic epoxy resin. Besides, a variety of functional polymer can be formed by epoxy resin under catalytic homo-polymerization and self-polymerization, or polymerization of epoxy resin and other reactants such as poly-functional amine, acid (or acid anhydride), phenol, alcohol, thiols. Moreover, dependent on different situations, curing agents, accelerating agents, modifiers, diluting agents or fillers can be added into the taper aluminum-iron matrix composite for the adjustment of viscosity, reactivity or operation.

Photocurable polymer, which converts into cured resin by UV free-radical polymerization, has advantages as follows:

(1) energy saving: for photopolymerization, the energy is provided for ensuring active chemical ingredient to go cross-linked polymerization under UV radiation. It is not necessary to heat a Whole substrate. As a result, the consumption of photocurable paint and ink can be one fifth of regular solvent paint and curable ink.

(2) environment-friendly: it is beneficial to environment protection because any volatile solvent is not used as the active chemical ingredient in photopolymerization, so that photopolymerization in the present invention is zero release technology.

(3) High profit: equipment used for photopolymerization are compact, rapid-processing, high efficiency, and occupy little space, which is beneficial to improvement on product properties, consumption reduction of raw materials, and competition enhancement on technical capacity.

Sheet 1 is a datasheet showing the absorptivity of infrared thermal radiation of taper aluminum-iron matrix composite. Please refer to sheet 1, during the waveband of mid-infrared rays from 3 μm to 5 μm and from 8 μm to 12 μm, polymer and composite thereof are measured to check whether the infrared thermal radiation from the target object is reduced. A reflection ratio is detected by an infrared spectrometer of attenuated total reflection (AIR), and the absorptivity is acquired by converting reflection ratio under zero transmittance. The value of absorptivity is regarded as the reduction effect of the infrared thermal radiation from the target object. Though infrared thermal radiation can be decayed and disturbed by vapor and carbon dioxide of atmosphere, however, the absorption of infrared thermal radiation by atmosphere is weak during the wavebands of 3 μm-5 μm and 8 μm-12 μm. As a result, the transmittance of infrared thermal radiation in atmosphere is high and easy to be observed in the two wavebands, and thus, such the two wavebands are selected for the measurement of infrared thermal radiation influenced by the polymer and the composite thereof. Epoxy resin is of a specific structure to enable a cured structure have obviously effect on the reduction of the infrared thermal radiation from the target object. With absorbed infrared rays, epoxy resin makes molecule structure generate resonance to reduce the infrared reflection ratio of the target object. In the wavebands of 3 μm-5 μm and 8 μm-12 μm and compared with polymethylmethacrylate (PMMA), the infrared absorptivity of epoxy resin are increased 7% and 9.5%, respectively. Besides, after the addition of the taper bimetallic aluminum-iron of 15% to 20% to form taper bimetallic aluminum-iron matrix composite, the infrared absorptivities of epoxy resin taper bimetallic aluminum-iron matrix composite are further raised 3.2% and 13.6%, respectively, at the wavebands of 3 μm-5 μm and 8 μm-12 μm. On the other hand, the infrared absorptivity of polymethylmethyacrylate (PMMA) taper aluminum-iron matrix composite are increased 10.2% and 0.72%, respectively, at the wavebands of 3 μm-5 μm and 8 μm-12 μm. It is shown that the taper bimetallic aluminum-iron matrix composite has obvious effect on the reduction of the infrared thermal radiation from the target object. It is noted that there are no obvious differences in the infrared absorptivities between a traditional aluminum metal-matrix composite and the taper bimetallic aluminum-iron matrix composite. Accordingly, the taper bimetallic aluminum-iron matrix composite of the present invention has equivalent effect as a traditional composite material.

Sheet 1: infrared absorptivity of taper bimetallic
aluminum-iron matrix composite

| | Aluminum | Bimetallic | absorptivity | absorptivity |
|---|---|---|---|---|
| polymer | metal (%) | aluminum-iron (%) | (3~5 μm) | (8~12 μm) |
| Epoxy | — | — | 0.94 | 0.81 |
| | — | 20 | 0.97 | 0.92 |
| PMMA | — | — | 0.88 | 0.74 |
| | 15 | — | 0.97 | 0.91 |
| | 20 | — | 0.96 | 0.86 |
| | — | 15 | 0.97 | 0.90 |
| | — | 20 | 0.96 | 0.86 |

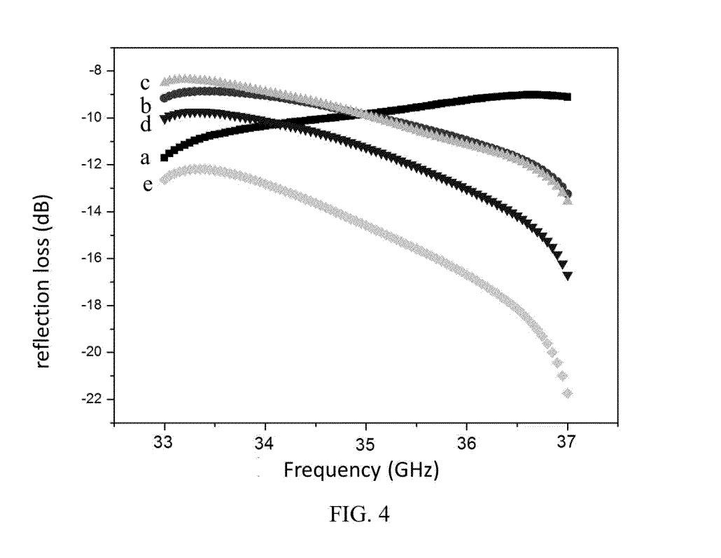

FIG. 4 is a diagram illustrating reflection loss on millimeter wave for PMMA taper aluminum-iron matrix composite according to the present invention. Please refer to FIG. 4, lines “b”, “c”, “d”, “e” represent different composite materials by adding aluminum metal (Al) and bimetallic aluminum-iron (Al—Fe) of different ratios into PMMA. and their reflection losses in a high frequency zone of 33 GHz to 37 GHz are measured. It is shown that in the case of the taper aluminum-iron matrix composite to be added up to 20%, the reflection loss will have the best value of −22 dB at 37 GHz. On the other hand, line “a” representing an absorptive resin plate “a” has the value of −9 dB for the reflection loss at 37 GHz. Compared with the Absorptive resin plate “a”, the taper aluminum-iron matrix composite of 20% addition can have increscent 144% in the reflection loss. Furthermore, in the case of the aluminum matrix composite added up to 20%, the reflection loss will have the best value of −13.5 dB at 37 GHz. Thus, compared with the aluminum matrix composite, the taper aluminum-iron matrix composite of 20% addition can have increscent 63% in the reflection loss. Accordingly, for the measurements on the losses of the energy of millimeter wavelength through the photo-cured PMMA taper aluminum-iron matrix composite, in the band of 33 GHz to 37 GHz, there is the best effect on the energy of millimeter wavelength absorbed by the taper bimetallic aluminum-iron.

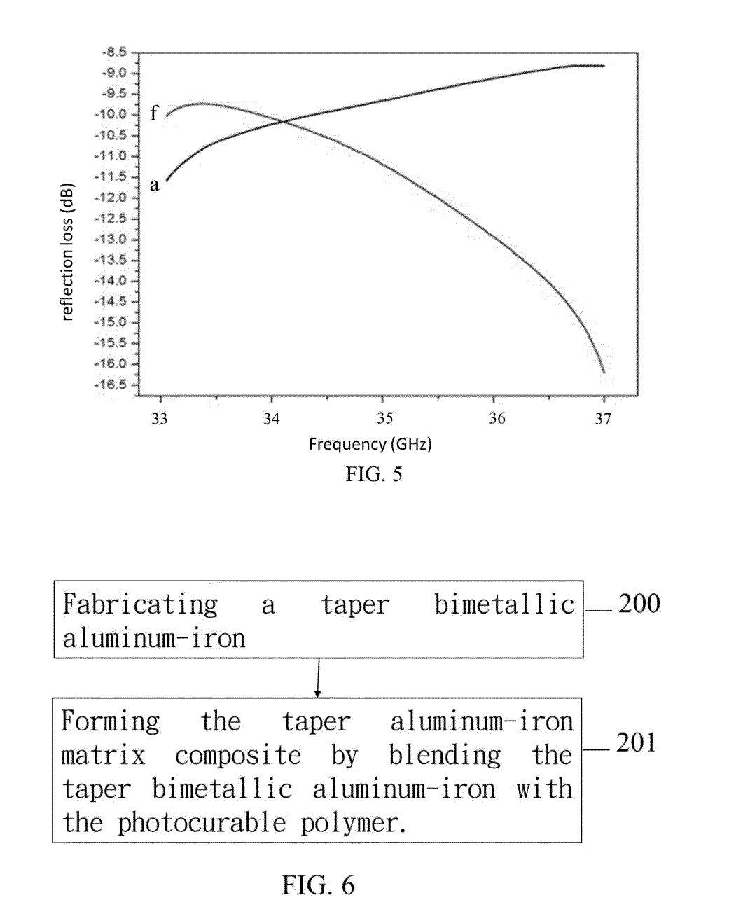

FIG. 5 is a diagram illustrating reflection loss on millimeter wave for epoxy taper aluminum-iron matrix composite according to the present invention. In FIG. 5, line “f” represents a metal matrix composite by adding 20% taper bimetallic aluminum-iron into epoxy, and its reflection losses are measured at a high frequency zone of 33 GHz to 37 GHz. The reflection loss at 37 GHz is −6.25 dB. On the other hand in FIG. 4, the reflection loss of the taper aluminum-iron matrix composite of 20% addition is −22 dB. Consequently, the reflection loss of the epoxy metal-matrix composite is descent 25%. However, it does not mean that the epoxy metal-matrix composite has poorer performance than the PMMA ones. According to Sheet 1, the epoxy metal-matrix composite performs better infrared absorptivity than the PMMA one does. Accordingly, dependent on various requirements, the taper aluminum-iron matrix composites can be fabricated by selecting various polymers to perform their most utilization thereof.

FIG. 6 is a flow chart illustrating the formation method of the taper aluminum-iron matrix composite according to the present invention. Please refer to FIG. 6, step 200: a taper bimetallic aluminum-iron is fabricated by a method similar to the one aforementioned, so it is not repeated here. Step 201: the taper bimetallic aluminum-iron is blended with the photocurable polymer to form the taper aluminum-iron matrix composite. The types, structures, functions, and properties of the photocurable polymer are similar to the ones aforementioned, too. Dependent on different situations, curing agents, accelerating agents, modifiers, diluting agents, or fillers can be added into the taper aluminum-iron matrix composite for the adjustment of viscosity, reactivity or operation. Meanwhile, in step 200 of this embodiment, any taper composite metal 1 can be used, not limited to the taper bimetallic aluminum-iron.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A taper composite metal-matrix composite comprising.
a taper composite metal comprising a flake metal substrate and a plurality of taper metal nanorods, wherein the taper metal nanorods are formed on the flake metal substrate; and
a polymer being a photocurable polymer, wherein the taper composite metal-matrix composite is prepared from a blend comprising the taper composite metal and the polymer.

2. The taper composite metal-matrix composite of claim 1. wherein a material of the taper metal nanorods comprises titanium, iron, nickel, copper, zinc, or aluminum.

3. The taper composite metal-matrix composite of claim 1, wherein a material of the flake metal substrate comprises titanium, iron, nickel, copper, zinc, or aluminum.

4. The taper composite metal-matrix composite of claim 1, wherein a plurality of heights of the taper metal nanorods are from 5 nm to 100 nm.

5. The taper composite metal-matrix composite of claim 1, wherein a plurality of lengths of the taper metal nanorods are from 5 nm to 10 nm.

6. The taper composite metal-matrix composite of claim 1, wherein a plurality of widths of the taper metal nanorods are from 5 nm to 10 nm.

7. The taper composite metal-matrix composite of claim 1, wherein a mean roughness Rz of the flake metal substrate is from 30 to 40.

8. The taper composite metal-matrix composite of claim 1, wherein the photocurable polymer comprises bisphenol A epoxy resin, bisphenol S epoxy resin, bisphenol F epoxy resin, bisphenol P epoxy resin, hydrogenated bisphenol A epoxy resin, hydroxymethyl bisphenol A epoxy resin, polyether epoxy resin, polyurethane modified epoxy resin, polysiloxane modified epoxy resin, Novolac epoxy resin, aliphatic epoxy resin, and heterocyclic epoxy resin.

9. The taper composite metal-matrix composite of claim 1, wherein the taper composite metal-matrix composite has a waveband of electromagnetic shielding and absorption comprising mid-infrared rays and extremely high frequency of radio wave.

10. A fabricating method of taper aluminum-iron matrix composite comprising:
forming an aluminum solution by pouring deionized water into a beaker having flake aluminum powder and stirring;
preparing a solution of ferric chloride by solving ferric chloride with deionized water;
reacting the aluminum solution with hydrochloric, acid completely, and adding the solution of ferric chloride into the reacted aluminum solution to form a taper bimetallic aluminum-iron, wherein a plurality of taper iron nanorods are formed on surface of the flake aluminum powder;
implementing filtering by air suction and water rinsing; and
blending the taper bimetallic aluminum-iron and a photocurable polymer to form a taper aluminum-iron matrix composite.
